(19) United States
(12) Patent Application Publication
(10) Pub. No.: US 2026/0121377 A1
(43) Pub. Date: Apr. 30, 2026

(54) OPTICAL LINK WITH VCSEL WAVELENGTH MODULATION

(71) Applicant: Volantis Semiconductor, Inc., Portland, OR (US)

(72) Inventors: Tapabrata Ghosh, San Francisco, CA (US); John Sonkoly, Boise, ID (US)

(73) Assignee: Volantis Semiconductor, Inc., Portland, OR (US)

(21) Appl. No.: 19/230,233

(22) Filed: Jun. 6, 2025

Related U.S. Application Data
(63) Continuation-in-part of application No. 19/223,614, filed on May 30, 2025.
Application No. 19/223,614 is a continuation-in-part of application No. 19/222,606, filed on May 29, 2025.
Application No. 19/222,606 is a continuation-in-part of application No. 19/211,446, filed on May 19, 2025.
Application No. 19/211,446 is a continuation-in-part of application No. 19/210,116, filed on May 16, 2025.
Application No. 19/210,116 is a continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H01S 5/042; H01S 5/00; H01S 5/183; H04B 10/572; H04B 10/64

(52) U.S. Cl. CPC H01S 5/0427; H01S 5/0071; H01S 5/18305; H04B 10/572; H04B 10/64

(57) ABSTRACT

A first circuit sends electrical data. The electrical data is sent to a vertical-cavity surface-emitting laser (VCSEL). A wavelength of the VCSEL is modulated. The modulating includes emitting, by the VCSEL, a wavelength-modulated beam (WMB). The WMB is based on the electrical data that was sent. The modulating can be based on injecting current into the VCSEL. The modulating can be based on VCSEL chirp. The WMB is coupled optically to an optical medium. The optical medium comprises a waveguide or a fiberoptic cable. The coupling optically is accomplished using a grating coupler, a mirror, or an off-axis diffractive lens. The optical medium is further coupled to a wavelength-dependent optical element (WDOE). The WDOE decodes the WMB into the electrical data that was sent. The electrical data is delivered to a second circuit.

### RELATED APPLICATIONS

This application is a continuation-in-part of U.S. patent application “Optical Link With Modulation Of VCSEL Modes”Ser. No. 19/223,614, filed May 30, 2025.

The U.S. patent application “Optical Link With Modulation Of VCSEL Modes” Ser. No. 19/223,614, filed May 30, 2025, is also a continuation-in part of U.S. patent application “Optical Link With Polarization-Switched VCSEL Modulation” Ser. No. 19/222,606, filed May 29, 2025.

The U.S. patent application “Optical Link With Polarization-Switched VCSEL Modulation” Ser. No. 19/222,606, filed May 29, 2025, is also a continuation-in-part of U.S. patent application “Hierarchical Redundancy With Parallel Optical Links” Ser. No. 19/211,446, filed May 19, 2025.

The U.S. patent application “Hierarchical Redundancy With Parallel Optical Links” Ser. No. 19/211,446, filed May 19, 2025, is also a continuation-in-part of U.S. patent application “Waveguides Based On Nanoimprint Lithography On A Photonic Wafer Scale Interposer”Ser. No. 19/210,116, filed May 16, 2025.

The U.S. patent application “Waveguides Based On Nanoimprint Lithography On A Photonic Wafer Scale Interposer” Ser. No. 19/210,116, filed May 16, 2025, is also a continuation-in-part of U.S. patent application “Photonic Wafer-Scale Interposer With Mirrors Based on Nanoimprint Lithography”Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025 is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers”Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins”Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides”Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive”Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025, is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024, is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film”Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling”Ser. No. 63/714,353, filed Oct. 31, 2024.

Each of the foregoing applications is hereby incorporated by reference in its entirety.

### FIELD OF ART

This application relates generally to transmitting data and more particularly to an optical link with VCSEL wavelength modulation.

### BACKGROUND

Electromagnetic radiation is organized into the electromagnetic spectrum by wavelength. The classification bands range from short wavelength gamma radiation to long wavelength radio waves. Electromagnetic radiation is used in many technological fields such as medicine, communication, manufacturing, and scientific research. The bands most often used for communication are visible light, infrared, and radio which includes microwaves.

Visible light is the portion of the electromagnetic spectrum that is visible to human eyes. Even without the aid of technology, humans use visible light as a medium for communication by observing, using reflected light, one another's facial expressions and body language. Simple communication technologies such as writing, painting, smoke signals, and semaphore also rely on visible light. While these technologies rely on ambient light—that is, they do not produce light themselves but instead reflect light from their environment—technologies have also been developed that rely on emitted light. Signal fires were perhaps the first use of emitted visible light as a communication method, allowing for communication of important events over vast distances with far greater speed than a human could travel. Electrical signaling lights have also been used for similar purposes, and combining these advancements with morse code allowed for the communication of far more complex messages while retaining the speed and distance advantages of visible light.

Infrared radiation is the next largest wavelength range after visible light. One advantage of infrared radiation is that it is not visible to humans and thus does not generally carry the same risks of visual disruption or harm to eyesight. For example, television and other device remotes often use infrared light, allowing for invisible control of distant devices without the annoyance or potential injury of flashing lights. However, infrared light also shares the same limitation as visible light in that it is blocked by physical objects. Thus, the use of infrared light often requires a line of sight between the sender and receiver.

The next range of wavelengths after infrared comprises radio waves, including microwaves which are the smallest wavelength of this range. Microwaves are used in many long-distance communication technologies as they can travel longer distances than infrared waves. They are used to transmit information between points on the Earth's surface, to communicate from ground to satellites, in deep space communications, etc. Microwaves'relatively high frequency enables a larger information capacity than other radio waves. The larger waves of the radio wave band can pass around and through physical objects, allowing them to transmit information through walls and around mountains. They have enabled very long-range communication, including between indoor and outdoor locations, and can even penetrate deep underwater. Radio waves can safely be broadcast omnidirectionally, allowing them to be used for mass communication. Electromagnetic radiation has been indispensable in the development of communications technologies, with new applications allowing for even faster and more reliable long and short-range communication of ever-increasing amounts of information.

### SUMMARY

For several decades now, the demand for increased processor performance has grown exponentially. Computationally complex applications such as artificial intelligence (AI), climate modeling, genome sequencing, medical data processing, and so on have continued to strain the capabilities of what is possible with today's technology including processors, system-on-chips (SoCs), accelerators, servers, memory, power delivery, cooling technologies, and so on. The demand for additional processing performance will certainly remain strong. For example, today's large language model (LLM) training time can be measured in months, even with many processors and accelerators running 24×7. Making further improvements will require advances in all system components, including active devices, interconnection schemes, and architectures. For example, interconnections between processors, accelerators, memory, and so on must provide required data in a timely manner to support the data requirements of these processing elements to perform calculations. Otherwise, these processing elements can stall. The overall result would be that little, if any, overall performance improvement will be realized by the advanced processors without the data they need to process. Communication bandwidth, speed (latency), and power are each critical to overall system performance, both in today's high performance systems and the systems that will be created in the future.

Disclosed techniques enable improved data transmissions. A first circuit sends electrical data. The electrical data is sent to a vertical-cavity surface-emitting laser (VCSEL). A wavelength of the VCSEL is modulated. The modulating includes emitting, by the VCSEL, a wavelength-modulated beam (WMB). The WMB is based on the electrical data that was sent.

The modulating can be based on injecting current into the VCSEL. The modulating can be based on VCSEL chirp. The WMB is coupled optically to an optical medium. The optical medium comprises a waveguide or a fiberoptic cable. The coupling optically is accomplished using a grating coupler, a mirror, or an off-axis diffractive lens. The optical medium is further coupled to a wavelength-dependent optical element (WDOE). The WDOE decodes the WMB into the electrical data that was sent. The electrical data is delivered to a second circuit.

A method for transmitting data is disclosed comprising: sending electrical data, by a first circuit, to a vertical-cavity surface-emitting laser (VCSEL); modulating a wavelength of the VCSEL, wherein the modulating includes emitting, by the VCSEL, a wavelength-modulated beam (WMB), wherein the WMB is based on the electrical data that was sent; coupling optically the WMB to an optical medium, wherein the optical medium is further coupled to a wavelength-dependent optical element (WDOE); decoding, by the WDOE, the WMB into the electrical data that was sent; and delivering the electrical data that was decoded to a second circuit.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for an optical link with VCSEL wavelength modulation.

FIG. 2 is a flow diagram for modulating a wavelength of a VCSEL.

FIG. 3 is a cross-section of a VCSEL.

FIG. 4 is a cross-section of a VCSEL with a tuning region for wavelength control.

FIG. 5 is a block diagram of an optical link with modulation of VCSEL wavelengths.

FIG. 6 is an apparatus for an optical link with VCSEL wavelength modulation.

FIG. 7 is a system diagram for an optical link with VCSEL wavelength modulation.

### DETAILED DESCRIPTION

Techniques for transmitting data using a wavelength-switched receiverless link are disclosed. The relentless demand for increasing processing performance continues to push the present day capabilities of processors and other system elements. To meet these demands, high performance systems-on-chip (SoCs) have been designed that can include processors, memories, switching elements, and the like on a single chip. These SoCs can feature transistor counts in the tens of billions. To further computational capabilities that achieve system-level performance, accelerators, such as artificial intelligence (AI) accelerators, have been designed to offload and accelerate particularly complex calculations. For example, today's large language models can rely on many such scaled-out accelerators to perform training of and inferencing by the models. As raw processing power increases, the need for additional access bandwidth and speed to memory elements also increases, leading to advancements such as HBM memories where memory dies can be stacked on a single substrate.

The never-ending drive for performance has also spurred innovation in methods to interconnect system elements. In the past, simple bus architectures such as the Peripheral Component Interconnect (PCI) bus enabled adequate memory access bandwidth to prevent stalling of processor elements. However, as these various elements expanded their abilities to process more data more efficiently, additional methods of interconnect were developed. For example, high speed serial links such as PCI Express (PCIe) enabled Gigabit-per-second speeds on multiple “lanes.” As processing power has increased, optical communications have become a low power, high bandwidth alternative to wire-based techniques for transferring data between processing elements. For example, multimode fibers enable remarkably high bandwidth, short-reach optical links, which can be used between server racks, switches, storage, and so on.

Optical interconnect solutions have also been pursued to increase on-chip communications. For example, vertical-cavity surface-emitting lasers (VCSELS) can be used to generate light-based communication with a chip, a wafer, etc. with lower latency and improved bandwidth compared to traditional metal paths, especially when those paths are long. However, VCSELS have disadvantages which can limit their performance and increase power usage.

Traditionally, current is used to modulate a VCSEL. That is, once light is emitted, the intensity of the light can be adjusted by increasing or decreasing additional current. The optical power difference required to recognize a “1” (e.g., “on”) as opposed to a “0” (e.g., “off”) can be described as the extinction ratio of the VCSEL. A high extinction ratio is helpful for signal quality, ease of receiver sensing, and power usage. However, issues exist that can limit the effectiveness of VCSELs as an on-chip, on-wafer, on-interposer, etc. communication device. First, VCSELS can be associated with a threshold current, a minimum level of current which must be sent into the active area of the VCSEL before the VCSEL lasers and light can be emitted. This threshold current can reduce the extinction ratio and increase power usage.

Further, while optical power output (light intensity) of the VCSEL near the threshold can be linear, the power output can become non-linear as current is increased. Thus, modulating VCSEL intensity with current can lead to increased power usage to maintain a high extinction ratio, especially when many VCSELS are incorporated in a chip, wafer, interposer, and so on.

To address these issues, a wavelength-switched receiverless link is disclosed. Electrical data is sent by a first circuit to a vertical-cavity surface-emitting laser (VCSEL). A wavelength of the VCSEL is modulated. The wavelength can be based on current injection. The VCSEL emits a wavelength-modulated beam (WMB). The WMB is based on the electrical data that was sent. The WMB is coupled optically to an optical medium. The coupling optically can be accomplished by a mirror, such as a TMAH-etched mirror, a grating coupler, a bent waveguide, and so on. The coupling can include angling the WMB that was emitted by the VCSEL. The angling can be based on a micro-optical element (MOE) such as a micro lens, a diffractive optical element, a Fresnel lens, an asymmetric non-focusing optical device, and so on.

The optical medium is further coupled to a wavelength-dependent optical element (WDOE). The WDOE can comprise a grating coupler, a wavelength multiplexor (WMUX), and so on. The WDOE decodes the WMB into the electrical data that was sent. Each wavelength associated with an optical signal can be transformed by a unique photodiode. The transforming can result in one or more electrical signals. These electrical signals can be assembled into a single electrical signal. The single electrical signal can comprise the electrical data that was sent. The electrical data is delivered to a second circuit. The first circuit and the second circuit can include a first chiplet and a second chiplet, respectively. The first chiplet, the second chiplet, and the VCSEL can be within a plurality of chiplets bonded to a front side of a photonic wafer-scale integrations interposer (PWSI). The PWSI can include a plurality of waveguides. The optical medium can comprise a waveguide within the plurality of waveguides.

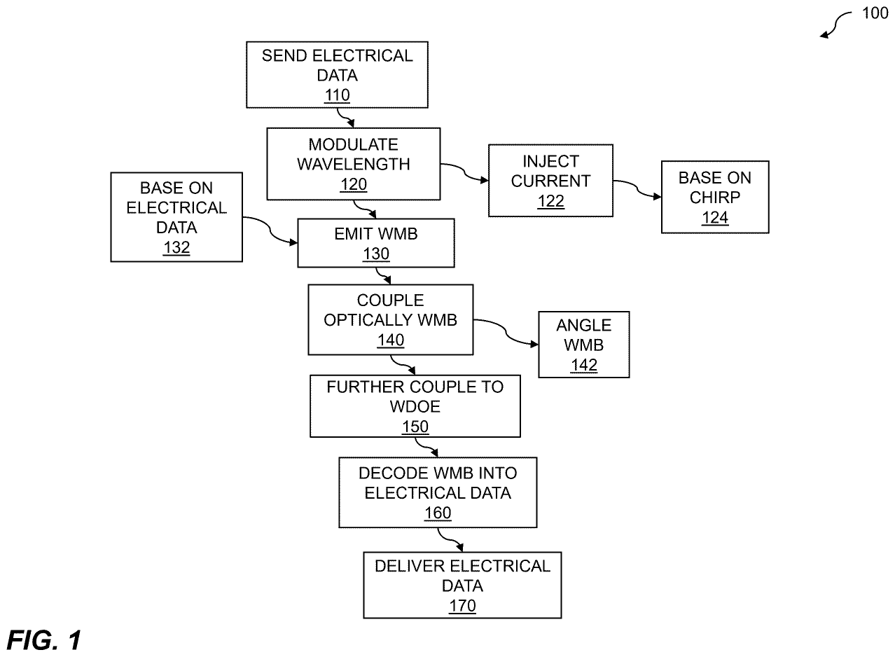

FIG. 1 is a flow diagram for an optical link with VCSEL wavelength modulation. The flow 100 includes sending electrical data 110. Embodiments include sending electrical data, by a first circuit, to a vertical-cavity surface-emitting laser (VCSEL). The first circuit can be a circuit within a chip, a core, a chiplet, an SoC, a wafer, an interposer, etc. The first circuit can comprise a processor, chiplet, multi-core processor, memory controller, memory chip such as DDR or HBM, I/O chip, AI accelerator, switching chip, and so on. The first circuit and the VCSEL can be on the same or different circuit boards, interposers, wafers, etc. The sending can be accomplished using any means to communicate between chips. For example, the sending can be based on routes on a printed circuit board, a bus interface, a wireless communication protocol such as Bluetooth, metal layers on a wafer or wafer interposer, and so on. The electrical data can comprise serialized data, data packets, handshaking signals, etc. A VCSEL can be a semiconductor laser fabricated on a chip. The fabrication can be based on gallium arsenide or another suitable material. The VCSEL can emit light in a perpendicular direction to the chip.

The direction can be up (e.g., away from the chip) or down (e.g., into the chip). When light is emitted down, an aperture or a window can be provided so that the light can escape through the back of the chip. To aid projection of the light, the substrate of the chip can be thinned. The light that is emitted can be coherent light that is in a wavelength range, such as 850 nm-950 nm. Other ranges are possible.

The flow 100 includes modulating a wavelength 120 of the VCSEL. Embodiments include modulating a wavelength of the VCSEL, wherein the modulating includes emitting, by the VCSEL, a wavelength-modulated beam (WMB), wherein the WMB is based on the electrical data that was sent. Modulation can include adjusting properties of light emission of the VCSEL to encode optical data. The encoding can be based on the presence or absence of a light wavelength; two light wavelengths, where one wavelength can represent a logic “0” and a second wavelength can represent a logic “1”; and the like. The modulation can include an encoding technique such as time-division multiplexing (TDM). For example, modulation can be based on current injected into the VCSEL. Adjusting the current applied to an active region of the VCSEL can turn light emission on and off, can vary the wavelength, etc. When the current is below a threshold, lasing action can be stopped. When current levels return to a level exceeding the threshold, lasing can restart. As current is increased, a brightness, or optical power, of the VCSEL can be increased. The detection of a presence or absence of light from the VCSEL can be used to encode a “1”or “0”in the form of a light wave.

Modulation can include changing properties of the light that is emitted. For example, modulation can include a mode, a polarization, and so on. Modulation can also include changing a wavelength of the light emitted by the VCSEL, as disclosed herein. The modulation of the light emitted by the VCSEL can be controlled based on a current applied to the active area of the VCSEL. In embodiments, the modulating further comprises injecting current 122 into the VCSEL. The injecting can be accomplished using one or more p-contacts and one or more n-contacts, where the one or more p-contacts and the one or more n-contacts are coupled to the active region of a VCSEL (discussed below). The injecting current can affect the wavelength emitted by the VCSEL. In embodiments, the modulating is based on VCSEL chirp 124. A “chirp,” which is a temporal change, can cause a change in wavelength of light emitted by a VCSEL. In a usage example, a VCSEL chirp can include a 1 nm to 2 nm change in emitted wavelength. The chirp can be dependent on a variety of VCSEL parameters including dynamic behavior of carrier density in a VCSEL active region, differential gain, etc. The chirp can include a positive change in wavelength or a negative change in wavelength.

The flow 100 includes emitting a wavelength-modulated beam (WMB) 130. A WMB can result from modulating the resonance of an active region within a VCSEL. The WMB can comprise an optical signal with wavelengths of light that vary over time, thus encoding optical information. The wavelength of the beam can be sensed, allowing for the information that is sent to be decoded. Recall that electrical data is sent by a first circuit to a VCSEL. The electrical data can be used to modulate a wavelength of the VCSEL by disclosed techniques, resulting in a WMB sent from the VCSEL. Thus, in the flow 100, the WBM is based on the electrical data that was sent 132.

The flow 100 includes coupling optically the WBM 140. Embodiments include coupling optically the WMB to an optical medium, wherein the optical medium is further coupled to a wavelength-dependent optical element (WDOE). An optical medium can be any material, space, etc. that allows an optical signal, such as a WBM, to propagate. In embodiments, the optical medium comprises a waveguide. The waveguide can include a waveguide within a wafer, an interposer, and so on. The first circuit and the VCSEL can be bonded to a photonic wafer-scale interposer (PWSI) which includes a plurality of waveguides to carry optical signals from one or more VCSELs. The optical medium can comprise a waveguide within the plurality of waveguides. Recall that the VCSEL can emit optical signals, such as the WBM, in a vertical direction. The vertical direction can be down, toward the substrate (and the PWSI to which a VCSEL can be bonded). A waveguide within the PWSI can be oriented horizontally or substantially horizontally. Thus, the WBM can be coupled to the waveguide in order for it to propagate along the waveguide to another circuit bonded to the PWSI, such as a second circuit. Other optical mediums can be used. In embodiments, the optical medium comprises a fiberoptic cable. In a usage example, a fiberoptic cable is used as an optical medium to send an optical signal from a transmitter to a receiver. In a usage example, the optical medium comprises a wavelength maintaining (e.g., low loss) fiber. The wavelength maintaining fiber can maintain fidelity of the WMB.

In embodiments, the coupling optically is based on a grating coupler. The grating coupler can diffract light at specific frequencies, frequency ranges, input angles, etc., thereby providing efficient transfer of light at a specific frequency and/or frequency range into or out of a waveguide. To aid the coupling to a grating coupler, the WBM emitted from the VCSEL can be angled. Embodiments include angling 142 the WMB that was emitted by the VCSEL, wherein the angling is based on a micro-optical element (MOE). The MOE can be based on one or more optical techniques. For example, the MOE can comprise a micro lens. The micro lens can be coupled to the first surface-emitting light source such as a VCSEL, an LED, a laser diode, and so on. The micro lens can pre-angle the emitted light. The MOE can comprise a diffractive optical element. The diffractive optical element can create a light phase profile that can focus, shape, or split the emitted light. The MOE can include a Fresnel lens. The Fresnel lens can use concentric grooves or rings to focus the emitted light. The MOE can include an asymmetric non-focusing optical device. The asymmetric non-focusing optical device can enable light to transmit through the device preferentially, where the light can pass through more easily in one direction than another direction. The asymmetric non-focusing optical device can couple light to a waveguide and can suppress a portion of reflected light back to the surface-emitting light source. Any number and/or types of MOEs can be used in conjunction with any number of VCSELS.

Other methods of coupling the WMB to an optical medium, such as a waveguide, can be implemented. In embodiments, the coupling optically is based on a mirror. The mirror can include a mirror within a wafer, an interposer, and so on. In a usage example, the coupling is based on a crystallographic etched mirror. The crystallographic etched mirror can comprise a tetramethylammonium hydroxide (TMAH) etched mirror. The TMAH mirror can reflect incoming light at a 54.74 degree angle to the waveguide. Other angles are possible with various crystallographic etched mirrors. A crystallographic etched mirror can operate in combination with a MOE, such as described above, which can be placed over or near an aperture of the VCSEL. For example, the MOE can pre-angle light from the VCSEL so that when the light is reflected by the TMAH mirror, it is efficiently coupled directly into the waveguide at 90 degrees, or sufficiently close to 90 degrees, from the light source. In other embodiments, the coupling is based on a bent waveguide. The bent waveguide can include a high containment region of a waveguide. The high containment waveguide can redirect light such as the WMB while minimizing loss of light in the region of the bend of the waveguide. In embodiments, the coupling optically is based on an off-axis diffractive lens. An off-axis diffractive lens can direct light at an angle with respect to the optical axis of the lens.

In the flow 100, the optical medium is further coupled to a wavelength-dependent optical element (WDOE) 150. A WDOE can be an optical element that interprets a wavelength state of an optical signal. The WDOE can be used to decode the WMB at the far end of the optical medium. The flow 100 includes decoding the WMB into electrical data 160.

Embodiments include decoding, by the WDOE, the WMB into the electrical data that was sent. The WDOE can be based on a variety of optical techniques. In some embodiments, the WDOE comprises a grating coupler. The grating coupler can separate different wavelengths of light from each other. In a usage example, the separated wavelengths of light can be sent to optical receivers, where the optical receivers can convert the optical data to electrical data. In other usage examples, the WDOE can include a wavelength filter. A wavelength filter can enable passage of light with a wavelength that is compatible with the wavelength filter while substantially blocking light with wavelengths that are incompatible with the wavelength filter. In a usage example, a first wavelength filter passes light with a first wavelength, and a second wavelength filter passes light with a second wavelength. The decoding performed by the WDOE can include demultiplexing. The decoding can include time-division demultiplexing (TDDM). The TDDM can reassemble two or more signals that were sent time-multiplexed before sending through the optical medium.

The flow 100 includes delivering electrical data 170. Embodiments include delivering the electrical data that was decoded to a second circuit. The second circuit can be a circuit within a chip, a core, a chiplet, an SoC, a wafer, an interposer, etc. The second circuit can comprise a processor, chiplet, multi-core processor, memory controller, memory chip such as DDR or HBM, I/O chip, AI accelerator, switching chip, and so on. The first circuit and the second circuit can be on the same or different circuit boards, interposers, wafers, etc. In embodiments, the first circuit and the second circuit comprise a first chiplet and a second chiplet, respectively. The first and second chiplets can be within a plurality of chiplets bonded to a photonic wafer-scale interposer (PWSI). The electrical data can be delivered to the second circuit using a variety of techniques. The delivery techniques can be based on using wire, interconnect, metal layers, and so on. The metal layers can include metal layers within a circuit board, a wafer, an interposer, and the like. The interposer can include a photonic wafer-scale interposer. The metal layers, which enable interconnection between and among circuits and other elements, can be fabricated on or within a circuit board, wafer, or interposer. As was the case for sending the data from the first circuit to the VCSEL, using the metal layers offers significant inter-chiplet communications speed due to short wire lengths, and reduced “parasitics” such as resistance, capacitance, and inductance. The second circuit can process the delivered data, forward the delivered data, store the delivered data, etc.

Various steps in the flow 100 may be changed in order, repeated, omitted, or the like without departing from the disclosed concepts. Various embodiments of the flow 100, or portions thereof, can be included in an apparatus for transmitting data or system that is configured to transmit data.

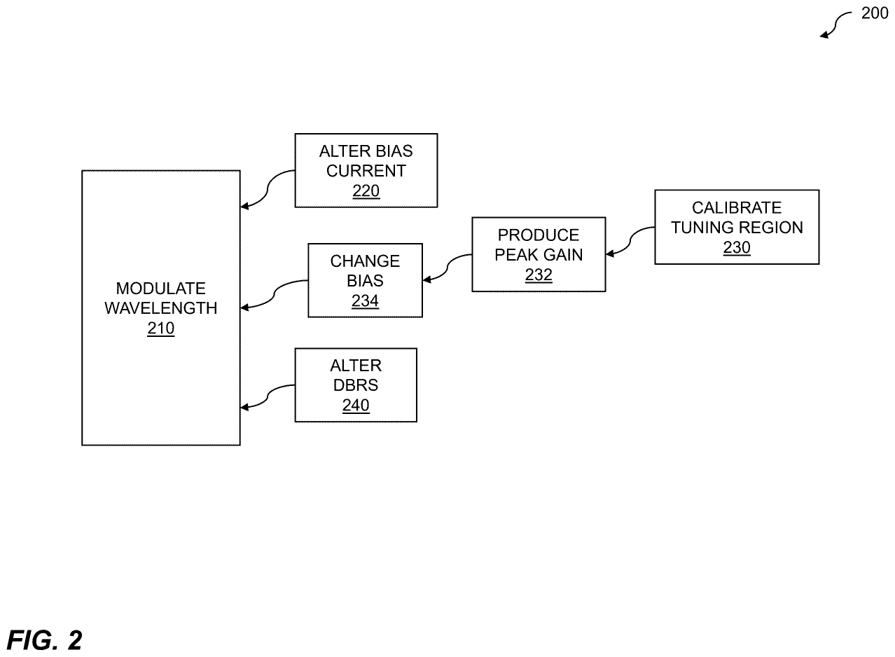

FIG. 2 is a flow diagram for modulating a wavelength of a VCSEL. Modulating a VCSEL wavelength enables transmitting data using an optical link. The optical link is used to transmit data between a first circuit and a second circuit. The transmitting data is accomplished by sending the data to a vertical-cavity surface-emitting laser (VCSEL). The VCSEL emits light that is based on the sent data. A wavelength of the VCSEL is modulated, and the light that is emitted by the VCSEL is a wavelength-modulated beam (WMB). The modulating can be based on injecting current into the VCSEL. The modulating can be based on VCSEL chirp. The WMB is coupled to an optical medium which transmits the data to a wavelength-dependent optical element (WDOE) which is further coupled to the optical medium. The WDOE decodes the WMB into the electrical data that was sent. The decoding is accomplished by separating the wavelength-modulated beam. The decoded data is delivered as electrical data to a second circuit. The separating a wavelength-modulated beam enables an optical link with VCSEL wavelength modulation.

The flow 200 includes modulating 210 a wavelength of the VCSEL, wherein the modulating includes emitting, by the VCSEL, a wavelength-modulated beam (WMB), wherein the WMB is based on the electrical data that was sent. The modulating a wavelength can be accomplished based on current. In embodiments, the modulating further comprises injecting current into the VCSEL. The current can include a DC current, an AC current, a pulse, a sinusoid, and so on. The applied current can be altered in order to effect changes to the WMB. In the flow 200, the injecting includes altering 220 a bias current to the VCSEL. The altering the current can include increasing current, decreasing current, reversing current, and so on. In a usage example, the changing the current can change carrier density within an active region of the VCSEL. The changing carrier density within the active region can change the refractive index of the active region, and thus a resonance wavelength of the active region. In a further usage example, a higher current density can reduce the refractive index, thereby shifting the wavelength toward blue. A lower current density can increase the refractive index, thereby shifting the wavelength toward red.

In embodiments, the VCSEL includes a tuning region. The tuning region can be used to tune the active area, where tuning the active area effectively changes the length of the active area, and thus the wavelength of the light generated by the VCSEL. The generated wavelength of light can be within a range of wavelengths, a light band, and so on. Embodiments include calibrating the tuning region 230. The calibrating can include determining one or more electrical parameters that control the optical characteristics of the VCSEL. The parameters can further include determining temperature parameters that control the VCSEL optical characteristics. In a usage example, the calibrating can include determining one or more currents that can be required to switch between two or more spectral modes associated with the VCSEL. In embodiments, the calibrating produces a peak gain 232 of the VCSEL with substantially 0 volts tuning voltage. Calibrating the VCSEL for peak gain at substantially 0 volts can have the advantage of reducing the operating power requirements of the VCSEL. The calibrated tuning region of the VCSEL can enable modulation of the VCSEL. In embodiments, the modulating comprises changing an applied bias 234 to the tuning region. The applied bias can include an applied current, an applied voltage, or both an applied current and an applied voltage.

A length of active region of the VCSEL can be altered using a variety of techniques. The techniques can include electrical techniques, electro-mechanical techniques, and so on. In embodiments, the VCSEL comprises a micro-electro-mechanical-system VCSEL (MEMS VCSEL). A current, a voltage, and so on can be applied to the MEMS VCSEL to change a resonance wavelength of the active area of the VCSEL. In embodiments, the MEMS VCSEL comprises one or more adjustable Distributed Bragg Reflectors (DBRs). The DBRs can be adjusted, altered, and so on. The flow 200 further includes altering 240 the one or more adjustable DBRs, wherein the altering is based on a voltage. The voltage can be increased or decreased in order to adjust the one or more DBRs.

Various steps in the flow 200 may be changed in order, repeated, omitted, or the like without departing from the disclosed concepts. Various embodiments of the flow 200, or portions thereof, can be included in an apparatus for transmitting data or system that is configured to transmit data.

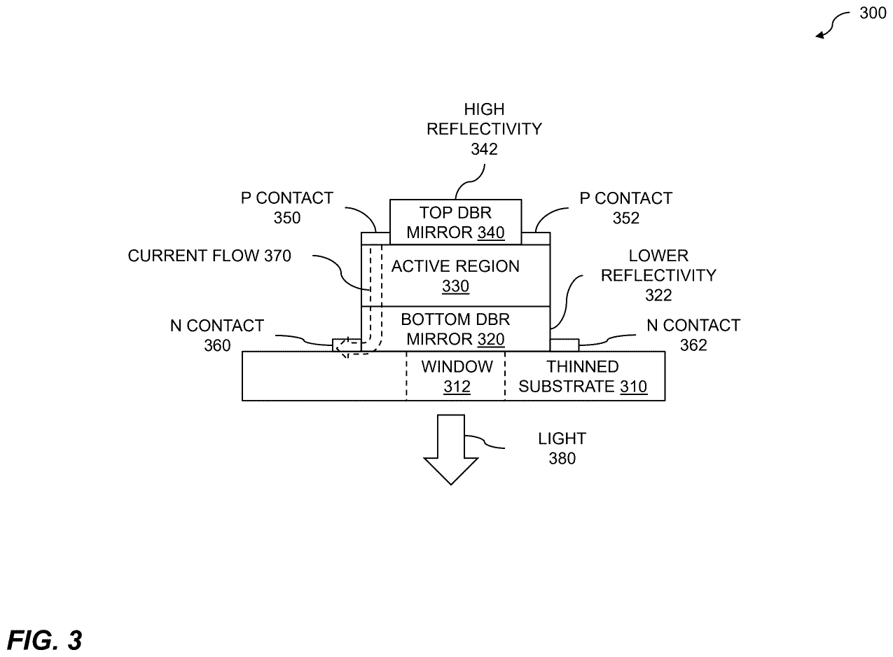

FIG. 3 is a cross-section of a VCSEL. A VCSEL enables optical links with wavelength modulation. A first circuit sends electrical data. The electrical data is sent to a vertical-cavity surface-emitting laser (VCSEL). A wavelength of the VCSEL is modulated. The modulating can be based on current injection, where the injecting includes altering a bias current to the VCSEL. The modulation causes the VCSEL to emit a wavelength-modulated beam (WMB). The WMB is based on the data that was sent by the first circuit. The WMB is coupled optically to an optical medium. The optical medium can comprise a waveguide. The coupling optically can be accomplished using a grating coupler, a mirror, and so on. The optical medium is further coupled to a wavelength-dependent optical element (WDOE). The WDOE decodes the WMB into the electrical data that was sent. The electrical data is delivered to a second circuit.

The first circuit and the second circuit can comprise a first chiplet and a second chiplet, respectively.

The block diagram 300 includes a thinned substrate 310. The thinned substrate can include a variety of materials suitable to fabricating a VCSEL. In a usage example, the substrate can include a gallium-arsenide (GaAs) substrate. Other materials that can be used for the substrate can include aluminum-gallium-arsenide (AlGaAs), germanium (Ge), sapphire, and so on. The substrate can be thinned to enable fabrication of an aperture or window 312. The thinning of the substrate can be accomplished by grinding, polishing, etching, and so on. Light in the form of a wavelength-modulated beam (WMB) is emitted by the VCSEL. The light emitted by the VCSEL can exit the VCSEL by passing through the window in the thinned substrate.

The VCSEL structure comprises an active region that is placed between two highly reflective mirrors. The first mirror includes a first reflectivity, and the second mirror includes a second reflectivity. In a usage example, the two highly reflective mirrors can be based on Distributed Bragg Reflectors (DBRs). These mirrors can be formed from multiple, alternating layers of materials, where the materials have different refractive indices. In the block diagram 300, a Distributed Bragg Reflector mirror can include a bottom mirror 320. The bottom mirror can include an n-Distributed Bragg Reflector. The bottom mirror can include a reflectivity that is lower than a top mirror (described below). In a usage example, the reflectivity 322 of the bottom DBR can include a “low” reflectivity of 93 percent to 99 percent, or another suitable reflectivity. The n-Distributed Bragg Reflectors associated with the bottom mirror can be insulated from other layers in the block diagram by an oxide layer (not shown).

The block diagram 300 includes an active region 330. The active region can comprise a region in which light that is emitted by the VCSEL can be generated. The light can be generated using a variety of techniques. In a usage example, the active region can include a structure such as a quantum well structure. The active region can be located within a laser cavity. The block diagram 300 can include an additional oxide layer (not shown) between the active region and a top DBR mirror. The oxide layer between the bottom mirror and the active area, and oxide layer between the active layer and the top mirror, may or may not be present in the VCSEL. When present, the oxide layers can confine the light and electrical current within the active area. The block diagram 300 includes a p-Distributed Bragg Reflector mirror 340. In the diagram 300, the p-Distributed Bragg Reflector mirror comprises the top mirror of the VCSEL. The top mirror can include a high reflectivity 342. In a usage example, the reflectivity of the top DBR can include a reflectivity of 99.4 percent to 99.9 percent. Other suitable reflectivities can be implemented.

An electrical current is applied to the VCSEL in order for the VCSEL to lase. The lasing of the VCSEL enables the VCSEL to emit coherent light. In embodiments, the modulating further comprises injecting current into the VCSEL. The injecting current can affect the wavelength emitted by the VCSEL. The applied or injected electrical current can include a DC current, a pulsed current, and so on. The current can include a symmetrical current, an asymmetrical current, etc. An injected asymmetrical current can include a current that is unbalanced or unequal with respect to distribution and/or direction. The applied current can modulate the light emitted by the VCSEL. In embodiments, the modulating is based on VCSEL chirp. A “chirp,” which is a temporal change, can cause a change in wavelength of light emitted by a VCSEL. In a usage example, a VCSEL chirp can include a 1nm to 2nm change in emitted wavelength. The chirp can be dependent on a variety of VCSEL parameters including dynamic behavior of carrier density in a VCSEL active region, differential gain, etc. The chirp can include a positive change in wavelength or a negative change in wavelength. In embodiments, the injecting includes altering a bias current to the VCSEL. The altering the bias current can cause a change in the wavelength of the light emitted by the VCSEL. In a usage example, the altering the bias current can change a density of carriers within the VCSEL. The change in carrier density can change a refractive index of the VCSEL, and thus the resonance wavelength of the VCSEL. In a second usage example, a higher carrier density reduces the refractive index, thereby shifting the emitted light wavelength toward blue wavelengths. The electrical current can be applied to contacts such as one or more p-contacts. In a usage example, the electrical current can be applied to a top p-contact. The p-contact can include a single contact, a ring contact, a “broken ring” contact where the ring is broken into two or more segments, and so on. In the FIG. 300, the contact to the VCSEL includes one or more p-contacts such as p-contact 350 and p-contact 352.

The electrical current that is injected into the VCSEL can exit the bottom of the VCSEL via one or more n-contacts. The n-contacts can include a single contact, a ring contact, a broken ring contact, etc. In the FIG. 300, the one or more n-contacts include n-contact 360 and n-contact 362. In a usage example, a p-contact ring and an n-contact ring can be concentric broken rings. By altering a bias current, a wavelength of light emitted by the VCSEL can be modulated. The electrical current flows 370 from a p-contact to an n-contact. The VCSEL emits light 380 via the VCSEL aperture or window 312. The light from the VCSEL can be emitted at an angle that can be substantially normal to a substrate, chip, PCB, interposer, etc. to which the VCSEL can be coupled. When there is a purpose for the light emitted by the VCSEL to be angled, then an optical device can be used. The purpose for angling the light can include enhancing optical coupling of the wavelength-modulated beam (WMB). Embodiments include angling the WMB that was emitted by the VCSEL, wherein the angling is based on a micro-optical element (MOE). The MOE can include a micro lens, a diffractive optical element, a Fresnel lens, an asymmetric non-focusing optical device, and so on.

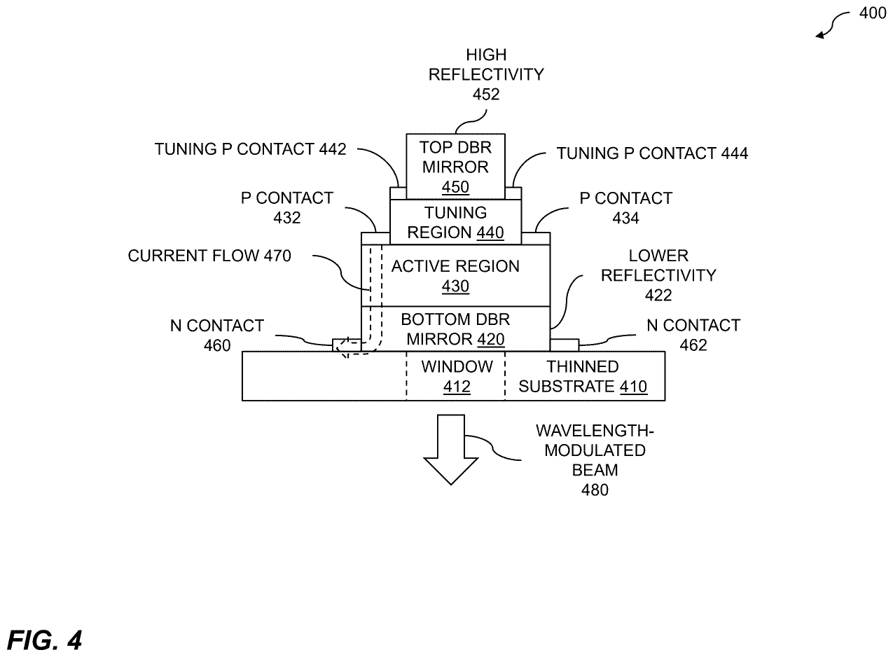

FIG. 4 is a cross-section of a VCSEL with a tuning region for wavelength control. A VCSEL enables optical links with wavelength modulation. In embodiments, the VCSEL includes a tuning region. The tuning region enables modulation of a beam emitted by the VCSEL. A first circuit sends electrical data. The electrical data is sent to a vertical-cavity surface-emitting laser (VCSEL). A wavelength of the VCSEL is modulated. The modulating can be based on current injection, where the injecting includes altering a bias current to the VCSEL. The modulation causes the VCSEL to emit a wavelength-modulated beam (WMB).

The altering bias current controls carrier densities within the VCSEL and thus wavelengths of light within the WMB. The WMB is based on the data that was sent by the first circuit. The WMB is coupled optically to an optical medium. The optical medium can comprise a waveguide. The coupling optically can be accomplished using a grating coupler, a mirror, and so on. The optical medium is further coupled to a wavelength-dependent optical element (WDOE). The WDOE decodes the WMB into the electrical data that was sent. The electrical data is delivered to a second circuit. The first circuit and the second circuit can comprise a first chiplet and a second chiplet, respectively.

The block diagram 400 includes a thinned substrate 410. Described previously, the thinned substrate can include a variety of materials suitable to fabricating a VCSEL such as gallium-arsenide (GaAs) substrate, an aluminum-gallium-arsenide (AlGaAs) substrate, a germanium (Ge) substrate, a sapphire substrate, and so on. The substrate can be thinned to enable fabrication of an aperture or window 412. Light in the form of a wavelength-modulated beam (WMB) is emitted by the VCSEL through the window in the thinned substrate.

The VCSEL structure comprises an active region coupled between two opposing highly reflective mirrors. A first mirror includes a first reflectivity, and a second mirror includes a second reflectivity. In a usage example, the two highly reflective mirrors can be based on Distributed Bragg Reflectors (DBRs). These mirrors can be formed from multiple, alternating layers of materials, where the materials have different refractive indices. In the block diagram 400, a Distributed Bragg Reflector mirror can include a bottom mirror 420. The bottom mirror can include an n-Distributed Bragg Reflector. The bottom mirror can include a reflectivity that is lower than a top mirror (described below). In a usage example, the reflectivity 422 of the bottom DBR can include a “low” reflectivity of 93 percent to 99 percent, or another suitable reflectivity. The n-Distributed Bragg Reflectors associated with the bottom mirror can be insulated from other layers in the block diagram by an oxide layer (not shown). A tuning region (described below) associated with the VCSEL can be coupled between the active area and a top mirror. The tuning region can tune the active region to a wavelength within a range of wavelengths.

The block diagram 400 includes an active region 430. The active region can comprise a region in which light that is emitted by the VCSEL can be generated. The light can be generated using a variety of techniques. In a usage example, the active region can include a structure such as a quantum well structure. The active region can be located within a laser cavity. The block diagram 400 can include an additional oxide layer (not shown) between the active region and a top DBR mirror. The oxide layer between the bottom mirror and the active area, and oxide layer between the active layer and the top mirror, may or may not be present in the VCSEL. When present, the oxide layers can confine the light and electrical current within the active area. The block diagram 400 includes a p-Distributed Bragg Reflector mirror 450. In the diagram 400, the p-Distributed Bragg Reflector mirror comprises the top mirror of the VCSEL. The top mirror can include a high reflectivity 452. In a usage example, the reflectivity of the top DBR can include a reflectivity of 99.4 percent to 99.9 percent. Other suitable values of reflectivity can be implemented.

The block diagram 400 includes a tuning region 440. The tuning region is used to tune the active area to enable the active area to generate a wavelength of light. The generated wavelength of light can be within a range of wavelengths, a light band, and so on. Embodiments include calibrating the tuning region. The calibrating can include determining one or more electrical parameters that control the optical characteristics of the VCSEL. The parameters can further include temperature characteristics. In a usage example, the calibrating can include determining one or more currents required to switch between two or more spectral modes of the VCSEL. In embodiments, the calibrating produces a peak gain of the VCSEL with substantially 0 volts tuning voltage. Calibrating the VCSEL for peak gain at substantially 0 volts can enable significant operating power reduction. The calibrated tuning region of the VCSEL can enable modulation of the VCSEL. In embodiments, the modulating comprises changing an applied bias to the tuning region. The applied bias can include an applied current, an applied voltage, or both an applied current and an applied voltage. The applied bias can be provided to the tuning region using one or more tuning contacts. The one or more contacts can include p-contacts. The contacts can comprise a ring, a broken ring, etc. In the FIG. 400, the one or more p-contacts can include tuning p-contact 442 and tuning p-contact 444.

A VCSEL can be based on a variety of techniques. In embodiments, the VCSEL comprises a micro-electro-mechanical-system VCSEL (MEMS VCSEL). The MEMS VCSEL can electro-mechanically adjust the length of laser cavity within the VCSEL, thereby enabling wavelength of the cavity. In other embodiments, the MEMS VCSEL comprises one or more adjustable Distributed Bragg Reflectors (DBRs). In this latter configuration, the DBR is moved based on an applied voltage, an applied temperature, and so on. Embodiments include altering the one or more adjustable DBRs, wherein the altering is based on a voltage. In further embodiments, the VCSEL includes a ferroelectric liquid (FLC) crystal layer. The FLC can enable high speed switching of the VCSEL, where the high speed switching can enable the modulation of light.

Discussed previously and throughout, an electrical current is used to enable the VCSEL to lase, where the lasing enables the VCSEL to emit coherent light. In embodiments, the modulating further comprises injecting current into the VCSEL. The injected current can modulate the light emitted by the VCSEL. In embodiments, the injecting includes altering a bias current to the VCSEL. The altering the bias current can cause a change in the wavelength of the light emitted by the VCSEL. Discussed above, in a usage example, the altering the bias current can change a density of carriers within the VCSEL. The change in carrier density can change a refractive index of the VCSEL, and thus the resonance wavelength of the VCSEL. In a second usage example, a higher carrier density reduces the refractive index, thereby shifting the emitted light wavelength toward blue wavelengths. The electrical current can be applied to contacts such as one or more p-contacts. In a usage example, the electrical current can be applied to a top p-contact. The p-contact can include a single contact, a ring contact, a “broken ring” contact where the ring is broken into two or more segments, and so on. In the FIG. 400, the contact to the VCSEL includes one or more p-contacts such as p-contact 432 and p-contact 434.

The electrical current that is injected into the VCSEL can exit the bottom of the VCSEL via one or more n-contacts. The n-contacts can include a single contact, a ring contact, a broken ring contact, etc. In the FIG. 400, the one or more n-contacts include n-contact 460 and n-contact 462. In a usage example, a p-contact ring and an n-contact ring can be concentric broken rings. By altering a bias current to the tuning region, and altering a bias current to the active region, a wavelength of light emitted by the VCSEL can be modulated. The electrical current flows 470 from a p-contact to an n-contact. The VCSEL emits light 480 via the VCSEL aperture or window 412. The light from the VCSEL can be emitted at an angle that can be substantially normal to a substrate, chip, PCB, interposer, etc. to which the VCSEL can be coupled. When there is a purpose for the light emitted by the VCSEL to be angled, then an optical device can be used. The purpose for angling the light can include enhancing the optical coupling of the wavelength-modulated beam (WMB). Embodiments include angling the WMB that was emitted by the VCSEL, wherein the angling is based on a micro-optical element (MOE). The MOE can include a micro lens, a diffractive optical element, a Fresnel lens, an asymmetric non-focusing optical device, and so on.

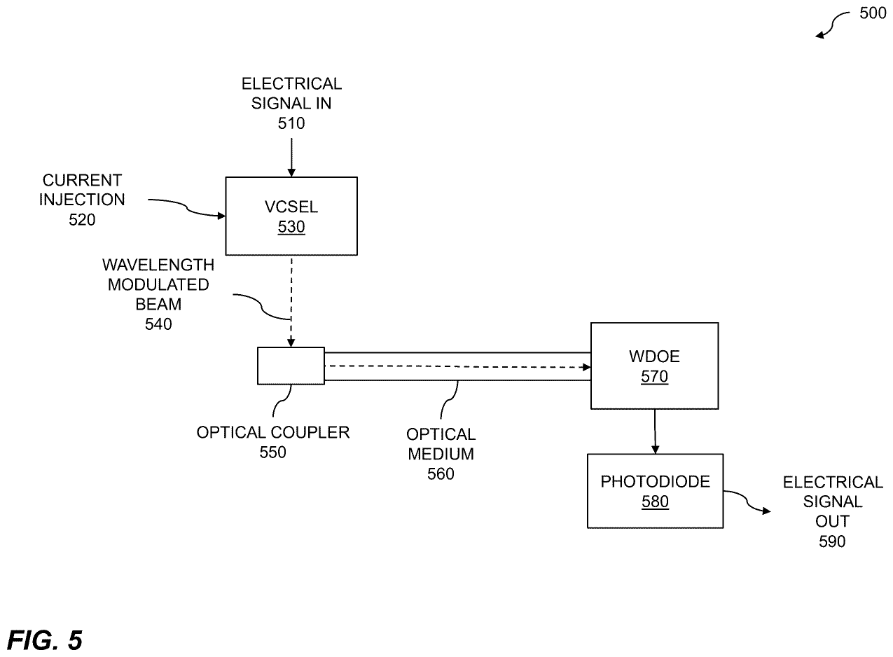

FIG. 5 is a block diagram of an optical link with modulation of VCSEL wavelengths. An optical link with VCSEL wavelength modulation enables transmitting data between a first circuit and a second circuit. A first circuit sends electrical data. The electrical data is sent to a vertical-cavity surface-emitting laser (VCSEL). A wavelength of the VCSEL is modulated. The modulating can be based on injecting current. The modulating can be based on VCSEL chirp. The modulation causes the VCSEL to emit a wavelength-modulated beam (WMB). The WMB is based on the data that was sent by the first circuit. The WMB is coupled optically to an optical medium. The optical medium can comprise a waveguide. The coupling optically can be accomplished using a grating coupler, a mirror, etc. The optical medium is further coupled to a wavelength-dependent optical element (WDOE). The WDOE decodes the WMB into the electrical data that was sent. The electrical data is delivered to a second circuit.

The block diagram 500 includes an electrical signal in 510. The electrical signal can represent data such as image data, video data, and audio data; artificial intelligence (AI) weights, biases, and data; natural language data; and so on. The electrical signal can represent parallel data such as data sent as bytes, words, etc. The electrical data can represent serial data. The block diagram 500 includes current injection 520. The current injection can comprise the basis for modulating a wavelength of a vertical-cavity surface-emitting laser (VCSEL). In embodiments, the injecting includes altering a bias current to the VCSEL. The altering the bias current can change current density within the active area of the VCSEL. The altering current density can change a refractive index of the VCSEL and thereby change the resonance wavelength of the VCSEL.

The injected current can be applied to a VCSEL 530. The injected current can be applied to contacts associated with the VCSEL in order generate an output of the VCSEL. In the block diagram 500, the modulating includes emitting, by the VCSEL, a wavelength-modulated beam (WMB) 540, wherein the WMB is based on the electrical data that was sent. The WMB can be directed through a VCSEL window or aperture toward an optical coupler 550. The optical coupler can include a coupler on or within a circuit board, a wafer, an interposer, etc.

The optical coupler can be based on a variety of optical elements, techniques, and so on. In embodiments, the coupling optically is accomplished by a grating coupler. The grating coupler can include a periodic grating that can transfer the WMB with low loss into the optical medium. In other embodiments, the coupling optically is based on a mirror. In a usage example, the mirror can include a nano-imprint lithography mirror. Embodiments include angling the WMB that was emitted by the VCSEL, wherein the angling is based on a micro-optical element (MOE) (not shown). The angling the PMB can be used to complement an angle associated with coupling the WMB to the optical medium.

The block diagram includes an optical medium 560. The optical medium can include a medium that is capable of transferring the WMB coupled to the optical medium by the optical coupler. The optical medium can include a waveguide on or within a wafer, an interposer, and so on. In a usage example, the optical medium can include a wavelength maintaining fiber. In embodiments, the optical medium comprises a fiberoptic cable.

The block diagram 500 includes a wavelength-dependent optical element (WDOE) 570 to which the optical medium is further coupled. The WDOE can be based on a variety of optical elements, optical techniques, and so on. The WDOE can separate different wavelengths of light from the WMB. The separated wavelengths of light (e.g., optical data) can be decoded into electrical data that was sent by the first circuit. The WDOE can accomplish decoding the WMB based on a variety of decoding techniques. In embodiments, the WDOE comprises a grating coupler. The grating coupler can separate different wavelengths of light from each other. In a usage example, the separated wavelengths of light can be sent to optical receivers, where the optical receivers can convert the optical data to electrical data. In another usage example, the grating coupler can indicate when a first wavelength is active in the optical medium, which can comprise a logic “1.” The absence of the signal from the grating coupler can comprise a logic “0.” Clocking, such as implementing clock and data recovery (CDR) circuits, can synchronize the WMB with the receiving and/or decoding circuits.

Some block diagram examples can include transforming each optical signal within the at least two optical wavelength signals, by a unique photodiode, to an electrical signal, The transforming would then result in at least two electrical signals. The block diagram 500 includes a photodiode 580. More than one photodiode can be included, where each photodiode can transform or decode an optical signal into an electrical signal. In the block diagram 500, the WDOE decodes the WMB into the electrical data that was sent. The decoded WMB is sent as an electrical signal out 590. Discussed previously, each optical signal within the at least two optical wavelength signals is transformed by a unique photodiode to an electrical signal. The transforming results in at least two electrical signals. The at least two electrical signals can be assembled into a single electrical signal, where the single electrical signal comprises the electrical data that was sent. The single electrical signal that includes the electrical data that was sent can be sent to a destination element such as a second circuit. The destination element can include a processor, an AI accelerator chiplet, a switching chiplet, etc. In embodiments, the first circuit and the second circuit comprise a first chiplet and a second chiplet, respectively. The first chiplet and the second chiplet can be bonded to a photonic wafer-scale interposer (PWSI).

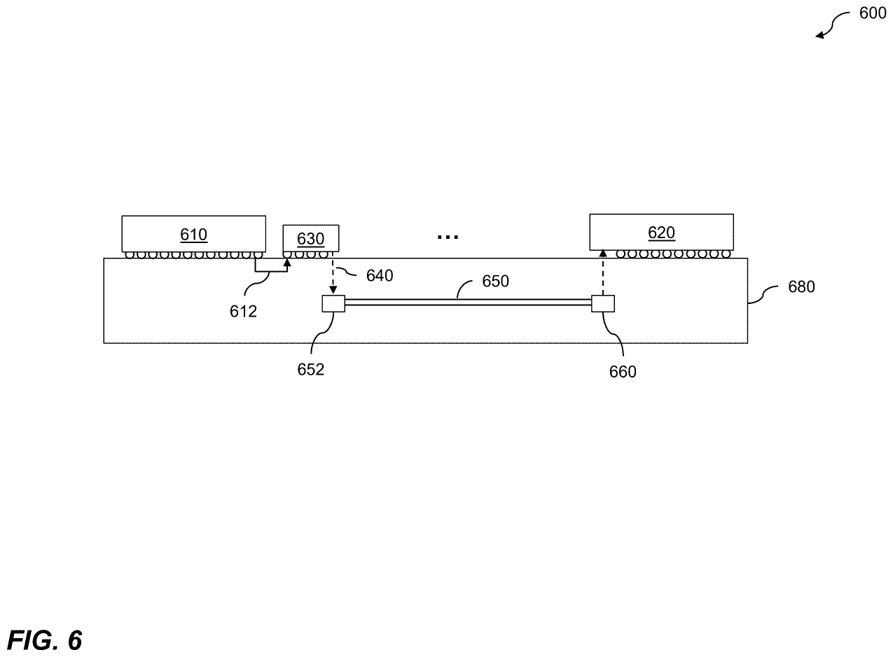

FIG. 6 is an apparatus for an optical link with VCSEL wavelength modulation. An optical link that enables transmitting data can be established. The optical link can be used to send data from a first circuit to a second circuit. In embodiments, the first circuit and the second circuit comprise a first chiplet and a second chiplet, respectively. The first circuit and the second circuit can be colocated on a circuit board, a wafer, or an interposer; located in different multiprocessors; located in different datacenters; and so on. In embodiments, a first circuit sends electrical data to a vertical-cavity surface-emitting laser (VCSEL). The VCSEL converts electrical data into optical data (e.g., light data). A wavelength of the VCSEL is modulated. The VCSEL modulation includes emitting, by the VCSEL, a wavelength-modulated beam (WMB). The WMB is based on the electrical data that was sent. By coupling the modulated beam to an optical medium such as a waveguide, a fiber, and so on, the WMB is sent via the optical medium to a wavelength-dependent optical element (WDOE). The WDOE decodes the WMB to electrical data. The electrical data is delivered to the second circuit. The apparatus enables transmitting data using an optical link with VCSEL wavelength modulation.

An apparatus is disclosed for transmitting data comprising: a first circuit, wherein the first circuit sends electrical data to a vertical-cavity surface-emitting laser (VCSEL), and wherein the VCSEL emits a wavelength-modulated beam (WMB); an optical medium, wherein the WMB is coupled optically, via an optical coupler, to the optical medium; a wavelength-dependent optical element (WDOE), wherein the WDOE is further coupled to the optical medium, wherein the WDOE converts the WMB into the electrical data that was sent; and a second circuit, wherein the second circuit receives the electrical data that was sent.

The apparatus 600 includes a first circuit 610, wherein the first circuit sends electrical data to a vertical-cavity surface-emitting laser (VCSEL) 630, and wherein the VCSEL emits a wavelength-modulated beam (WMB). In embodiments, the modulating further comprises injecting current into the VCSEL. The first circuit sends data to a second circuit 620 using the VCSEL and additional optical elements. The circuits can be connected, attached, bonded, or otherwise coupled to a circuit board, a wafer, an interposer, and so on. While two circuits and one VCSEL are shown, the apparatus can include any number of circuits and any number of VCSELs. The circuits can include AI accelerators, switching circuits, ASICS, I/O circuits, and so on. The first circuit sends 612 electrical data to the VCSEL. The VCSEL emits a wavelength-modulated beam (WMB). The WMB 640 can include a beam with a plurality of wavelengths. In a usage example, the WMB can include two wavelengths, where one wavelength represent a logic “1” and the second wavelength represents a logic “0.” In another usage example, two wavelengths can represent two different serial data streams. The first circuit can send data surface-emitting light sources that can be modulated, such as light emitting diodes (LEDs), laser diodes (LDs), and the like.

The WMB 640 emitted by the VCSEL is conveyed to an optical coupler 652. The apparatus 600 includes an optical medium 650, wherein the WMB is coupled optically, via an optical coupler, to the optical medium. The optical medium can include a low loss optical medium appropriate for sending the WMB. In embodiments, the optical medium comprises a waveguide. In other embodiments, the optical medium comprises a fiberoptic cable. In a usage example, the optical medium can include a wavelength maintaining fiber. The coupling optically can be accomplished by a grating coupler. The grating coupler can include a periodic grating that can transfer the WMB with low loss into the optical medium. The coupling optically can be accomplished by a mirror. In a usage example, the mirror can include a nano-imprint lithography mirror. Embodiments include angling the WMB that was emitted by the VCSEL, wherein the angling is based on a micro-optical element (MOE). The angling the WMB can be used to complement an angle associated with the coupling of the WMB to the optical medium. The angling can also compensate for variations in a wafer or interposer across the surface of the wafer or interposer. In a usage example, the WMB emitted by VCSEL can be pre-angled to an angle such as 9.74 degrees, and a mirror such as a crystallographic etched mirror can include an angle such as 54.74 degrees. The combination of pre-angling and angling can enable coupling the WMB to a waveguide at an angle substantially normal to an entrance aperture of the waveguide.

The MOE can be based on one or more optical techniques. The MOE can comprise a micro lens. The micro lens can be coupled to a first surface-emitting light source such as the VCSEL, a laser diode (LD), an LED, and so on. The micro lens can pre-angle the emitted light. The MOE can comprise a diffractive optical element. The diffractive optical element can create a light phase profile that can focus, shape, or split the emitted light. The MOE can comprise a Fresnel lens. The Fresnel lens can use concentric grooves or rings to focus the emitted light. The MOE can comprise an asymmetric non-focusing optical device. The asymmetric non-focusing optical device can enable light to transmit through the device preferentially, where the light can pass through more easily in one direction than another direction. The asymmetric non-focusing optical device can couple light to an optical medium such as a waveguide and can suppress a portion of reflected light back to the surface-emitting light source.

The apparatus 600 includes a wavelength-dependent optical element (WDOE) 660, wherein the WDOE is further coupled to the optical medium, wherein the WDOE converts the WMB into the electrical data that was sent. The WDOE can separate different wavelengths of light from the WMB. The separated wavelengths of light (e.g., optical data) can be decoded into electrical data that was sent by the first circuit. As described above and throughout, the WDOE can accomplish decoding based on a plurality of decoding techniques. In embodiments, the WDOE comprises a grating coupler.

The apparatus 600 includes a second circuit 620, wherein the second circuit receives the electrical data that was sent. The second circuit can receive the transmitted data that was sent by the first circuit. The first circuit and the second circuit can be located on a different or a common circuit board, a different or a common wafer, a different or a common rack, and so on. The first circuit and the second circuit can be remotely located with respect to each other. “Remotely located” can include locating the first circuit and the second circuit in separate circuit boards or wafers, separate multiprocessors, separate data racks, separate data centers, and so on. As shown in the apparatus 600, the first circuit, the second circuit, and the VCSEL can be coupled to a photonic wafer-scale interposer (PWSI) 680. The first circuit, the second circuit, and the VCSEL can be coupled to a circuit board, included within a chip, etc. Recall that in embodiments, the first circuit and the second circuit comprise a first chiplet and a second chiplet, respectively. In embodiments, the first chiplet, the second chiplet, and the VCSEL are within a plurality of chiplets bonded to a front side of a photonic wafer-scale interposer (PWSI), wherein the PWSI includes a plurality of waveguides and a plurality of through-silicon vias (TSVs), and wherein the optical medium comprises a waveguide within the plurality of waveguides.

The PWSI can enable high-speed communication between and among chiplets and VCSELs coupled to the PWSI. The PWSI can be configured to accomplish a variety of processing tasks. In embodiments, the PWSI comprises an optical wafer-scale AI accelerator, wherein one or more chiplets within the plurality of chiplets comprise one or more artificial intelligence (AI) accelerators. The AI accelerators can be used for training AI models and machine learning (ML) models, executing the AI models and the ML models, and the like. The AI models and ML models can be applied to processing applications such as video and image processing, audio processing and voice recognition, etc. In other embodiments, the PWSI comprises an optical wafer-scale network switch, wherein one or more chiplets within the plurality of chiplets comprise one or more switching chiplets. The optical wafer-scale network switch can be used for accessing and transferring large amounts of data such as data associated with training AI models and ML models. The optical wafer-scale network switch can transfer data to be processed by the trained models.

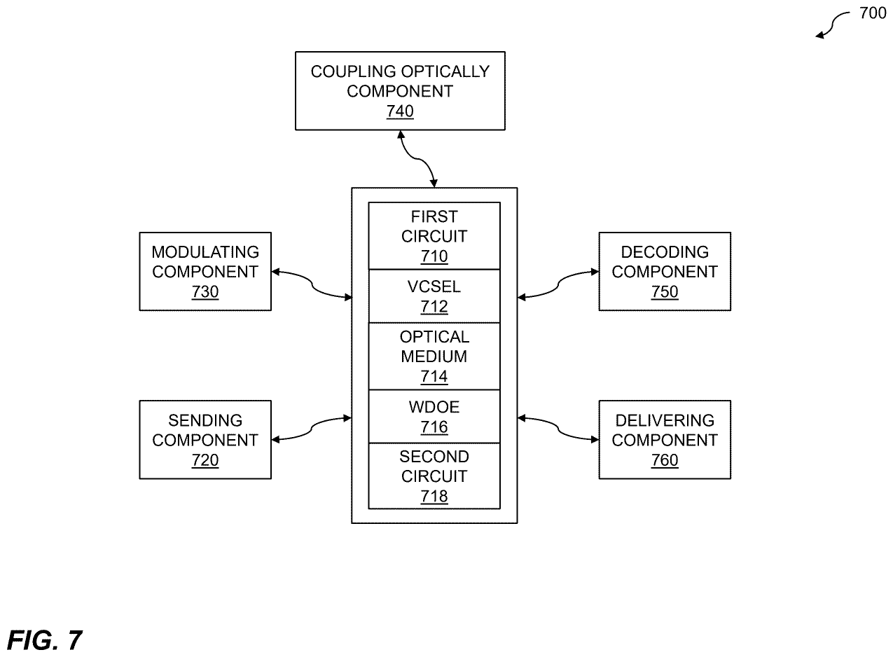

FIG. 7 is a system diagram for an optical link with VCSEL wavelength modulation. A first circuit sends electrical data. The electrical data is sent to a vertical-cavity surface-emitting laser (VCSEL). A wavelength of the VCSEL is modulated. The modulating can be based on injecting current into the VCSEL. The modulating can be based on VCSEL chirp. The injected current can include a bias current which can be altered. The modulation causes the VCSEL to emit a wavelength-modulated beam (WMB). The WMB is based on the data that was sent by the first circuit. The WMB is coupled optically to an optical medium. The optical medium can comprise a waveguide. The coupling optically can be accomplished using a grating coupler. The optical medium is further coupled to a wavelength-dependent optical element (WDOE). The WDOE decodes the WMB into the electrical data that was sent. The electrical data is delivered to a second circuit. The second circuit can be colocated within a plurality of circuits that also includes the first circuit. The second circuit can be located remotely from the first circuit. The sending, modulating, coupling, decoding, and delivering are enabled by an optical link with wavelength VCSEL modulation.

Disclosed is a system for transmitting data comprising: a first circuit, wherein the first circuit is coupled to a vertical-cavity surface-emitting laser (VCSEL); an optical medium, wherein the optical medium is coupled optically to an optical coupler; a wavelength-dependent optical element (WDOE), wherein the WDOE is further coupled to the optical medium; and a second circuit; wherein the system is configured to: send electrical data, by the first circuit, to the VCSEL; modulate a wavelength of the VCSEL, wherein the modulating includes emitting, by the VCSEL, a wavelength-modulated beam (WMB), wherein the WMB is based on the electrical data that was sent; couple optically, by the optical coupler, the WMB to the optical medium; decode, by the WDOE, the WMB into the electrical data that was sent; and deliver the electrical data to the second circuit.

The system 700 includes a first circuit 710, wherein the first circuit is coupled to a vertical-cavity surface-emitting laser (VCSEL) 712. As described earlier, the first circuit can be a circuit within a chip, a core, a chiplet, an SoC, a wafer, an interposer, etc. The first circuit can comprise a processor, chiplet, multi-core processor, memory controller, memory chip such as DDR or HBM, I/O chip, AI accelerator, switching chip, and so on. The VCSEL can include a VCSEL within a plurality of VCSELs. Other surface-emitting light sources can also be used. In a usage example, a surface-emitting light source can include a light emitting diode (LED), a laser diode (LD), and so on. The VCSEL can emit a wavelength-modulated beam (WMB). The system 700 includes an optical medium 714, wherein the optical medium is coupled optically to an optical coupler. The optical medium can include an optical fiber, an optical waveguide, and so on. In a usage example, the optical medium can include a wavelength maintaining fiber. Various optical couplers can be used to optically couple a wavelength-modulated beam (WMB) to the optical element. The optical coupler can comprise a grating coupler. The grating coupler can include a periodic grating that can transfer the WMB with low loss into the optical medium. Embodiments include angling the WMB that was emitted by the VCSEL, wherein the angling is based on a micro-optical element (MOE). The angling the WMB can be used to complement an angle associated with the coupling the WMB to the optical medium. Other optical couplers can include a mirror, a bent waveguide, an off-axis diffractive lens, etc.

The system 700 includes a wavelength-dependent optical element (WDOE) 716, wherein the WDOE is further coupled to the optical medium. The WDOE can distinguish between different wavelengths of light from the WMB emitted by the VCSEL. The WDOE can separate different wavelengths of light present in the WMB. The separated wavelengths of light can be decoded into electrical data that was sent by the first circuit. The WDOE can accomplish decoding based on a plurality of decoding techniques. In embodiments, the WDOE comprises a grating coupler. The grating coupler separates different wavelengths in the WMB from each other. The decoding can include time-division demultiplexing (TDDM). The separated wavelengths of light can be sent to optical receivers that convert the optical data to electrical data. In a usage example, an optical receiver can comprise a photodiode. The system 700 includes a second circuit 718. The second circuit can be a circuit substantially similar to the first circuit. In a usage example, the first circuit and the second circuit comprise artificial intelligence (AI) accelerators. In a second usage example, the first circuit and the second circuit comprise switching circuits. The second circuit can be substantially different in function, type of chip, pin layout, etc. than the first circuit. The second circuit can be colocated within a plurality of circuits that also includes the first circuit. The second circuit can be located remotely from the first circuit. In embodiments, the first circuit and the second circuit comprise a first chiplet and a second chiplet, respectively.

The system 700 includes a sending component 720. The sending component is configured to send electrical data, by the first circuit, to the VCSEL. The data can be sent by the first circuit to the VCSEL using one or more of wires, interconnect, metal layers, etc. The metal layers can include metal layers within a circuit board, a wafer, an interposer, and the like. The metal layers, which enable interconnection between and among chiplets and other elements, can be fabricated on or within a circuit board, wafer, or interposer. Using the metal layers offers significant inter-chiplet communications speed due to short wire lengths, and reduced “parasitics” such as resistance, capacitance, and inductance. The VCSEL can emit light based on the sent data. The emitted light represents the data as optical data. The emitted light can be modulated.

The system 700 includes a modulating component 730. The modulating component is configured to modulate a wavelength of the VCSEL, wherein the modulating includes emitting, by the VCSEL, a wavelength-modulated beam (WMB), wherein the WMB is based on the electrical data that was sent. The WMB can include a beam with a plurality of wavelengths. In a usage example, the WMB can include two wavelengths, where one wavelength represent a logic “1” and the second wavelength represents a logic “0.” In another usage example, two wavelengths can represent two different serial data streams. The first circuit can send data to other surface-emitting light sources that can be modulated, such as light emitting diodes (LEDs), laser diodes (LDs), and the like. The WMB can include wavelengths that can be modulated based altering a bias current, calibrating a tuning region of a VCSEL, VCSEL chirp, altering Distributed Bragg Reflectors (DBRs) and so on. The one or more modulated wavelengths of light can exit the VCSEL though an aperture or window associated with the VCSEL. The modulated light can exit the VCSEL at an angle substantially normal or perpendicular to the surface of the circuit board, wafer, interposer, etc. of which the VCSEL is coupled.

The system 700 includes a coupling optically component 740. The coupling optically component 740 is configured to couple optically, by the optical coupler, the WMB to the optical medium. The optical medium can include a low loss optical medium appropriate for sending the WMB. In embodiments, the optical medium comprises a waveguide. The waveguide can include a waveguide within a plurality of waveguides within a photonic wafer-scale interposer (PWSI). In other embodiments, the optical medium comprises a fiberoptic cable. In a usage example, the optical medium comprises a wavelength-maintaining fiber. The coupling optically is accomplished using an optical coupler. A variety of optical couplers can be used, as described above. In embodiments, the coupling optically is based on a mirror. In a usage example, the mirror can include a crystallographic etched mirror. Discussed throughout, the WMB can be angled by an MOE. In a usage example, the WMB emitted by VCSEL can be angled to substantially 9.74 degrees prior to being directed at a mirror. The mirror, such as a crystallographic etched mirror, can include an angle of 54.74. The angling the WMB compensates for the mirror angle deviation from 45 degrees, thereby enabling the coupling of the WMB to a waveguide at an angle substantially normal to an entrance aperture of the waveguide. The angling can also compensate for variations of a wafer or interposer across the surface of the wafer or interposer. In other embodiments, the coupling optically is based on a bent waveguide. In a usage example, the bent waveguide can include a high containment waveguide. The coupling optically can be accomplished using other optical elements as described previously.

The system 700 includes a decoding component 750. The decoding component 750 is configured to decode, by the WDOE, the WMB into the electrical data that was sent. The WDOE can separate distinct wavelengths of light from the WMB. The wavelengths can include a range of wavelengths. The separated wavelengths of light, which are based on optical data, can be decoded into electrical data. The decoding the optical data into electrical data can be accomplished using a photonic device such as a photodiode. The decoded electrical data is the data that was sent by the first circuit. As described above and throughout, the WDOE can accomplish decoding based on a plurality of decoding techniques, such as a grating coupler.

The system 700 includes a delivering component 760. The delivering component 760 is configured to deliver the electrical data to the second circuit. As was the case for the first circuit, the second circuit can comprise a circuit within a chip, a core, a chiplet, an SoC, a wafer, an interposer, etc. The second circuit can comprise a processor, chiplet, multi-core processor, memory controller, memory chip such as DDR or HBM, I/O chip, AI accelerator, switching chip, and so on. The first circuit and the second circuit can be colocated on the same chip, board, interposer, etc., or can be separated. The first circuit and the second circuit can be on different chips, interposers, racks, etc. The electrical data can be delivered by the delivering component to the second circuit using wire, interconnect, metal layers, and so on. The metal layers can include metal layers within a circuit board, a wafer, an interposer, and so on. The metal layers, which enable interconnection between and among circuits, chiplets, and other elements, can be fabricated on or within a circuit board, wafer, or interposer. As was the case for sending the data from the first circuit to the VCSEL, using the metal layers offers significant inter-circuit communications speed due to short wire lengths, and reduced “parasitics” such as resistance, capacitance, and inductance. The second circuit can process the delivered data, forward the delivered data, etc.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system” may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transmitting data comprising:
sending electrical data, by a first circuit, to a vertical-cavity surface-emitting laser (VCSEL);
modulating a wavelength of the VCSEL, wherein the modulating includes emitting, by the VCSEL, a wavelength-modulated beam (WMB), wherein the WMB is based on the electrical data that was sent;
coupling optically the WMB to an optical medium, wherein the optical medium is further coupled to a wavelength-dependent optical element (WDOE);
decoding, by the WDOE, the WMB into the electrical data that was sent; and
delivering the electrical data that was decoded to a second circuit.

2. The method of claim 1 wherein the modulating further comprises injecting current into the VCSEL.

3. The method of claim 2 wherein the modulating is based on VCSEL chirp.

4. The method of claim 2 wherein the injecting includes altering a bias current to the VCSEL.

5. The method of claim 1 wherein the VCSEL includes a tuning region.

6. The method of claim 5 further comprising calibrating the tuning region.

7. The method of claim 6 wherein the calibrating produces a peak gain of the VCSEL with substantially 0 volts tuning voltage.

8. The method of claim 5 wherein the modulating comprises changing an applied bias to the tuning region.

9. The method of claim 1 wherein the VCSEL comprises a micro-electro-mechanical-system VCSEL (MEMS VCSEL).

10. The method of claim 9 wherein the MEMS VCSEL comprises one or more adjustable Distributed Bragg Reflectors (DBRs).

11. The method of claim 10 further comprising altering the one or more adjustable DBRs, wherein the altering is based on a voltage.

12. The method of claim 1 wherein the VCSEL includes a ferroelectric liquid (FLC) crystal layer.

13. The method of claim 1 wherein the WDOE comprises a grating coupler.

14. The method of claim 1 wherein the optical medium comprises a waveguide.

15. The method of claim 14 wherein the coupling optically is based on a grating coupler.

16. The method of claim 15 further comprising angling the WMB that was emitted by the VCSEL, wherein the angling is based on a micro-optical element (MOE).

17. The method of claim 14 wherein the coupling optically is based on a mirror.

18. The method of claim 14 wherein the coupling optically is based on a bent waveguide.

19. The method of claim 14 wherein the coupling optically is based on an off-axis diffractive lens.

20. The method of claim 1 wherein the optical medium comprises a fiberoptic cable.

21. The method of claim 1 wherein the first circuit and the second circuit comprise a first chiplet and a second chiplet, respectively.

22. An apparatus for transmitting data comprising:
a first circuit, wherein the first circuit sends electrical data to a vertical-cavity surface-emitting laser (VCSEL), and wherein the VCSEL emits a wavelength-modulated beam (WMB);
an optical medium, wherein the WMB is coupled optically, via an optical coupler, to the optical medium;
a wavelength-dependent optical element (WDOE), wherein the WDOE is further coupled to the optical medium, wherein the WDOE converts the WMB into the electrical data that was sent; and
a second circuit, wherein the second circuit receives the electrical data that was sent.

23. The apparatus of claim 22 wherein the first circuit and the second circuit comprise a first chiplet and a second chiplet, respectively.

24. The apparatus of claim 23 wherein the first chiplet, the second chiplet, and the VCSEL are within a plurality of chiplets bonded to a front side of a photonic wafer-scale interposer (PWSI), wherein the PWSI includes a plurality of waveguides, and wherein the optical medium comprises a waveguide within the plurality of waveguides.

25. The apparatus of claim 24 wherein the PWSI comprises an optical wafer-scale AI accelerator, wherein one or more chiplets within the plurality of chiplets comprise one or more artificial intelligence (AI) accelerators.

26. The apparatus of claim 24 wherein the PWSI comprises an optical wafer-scale network switch, wherein one or more chiplets within the plurality of chiplets comprise one or more switching chiplets.

27. A system for transmitting data comprising:
a first circuit, wherein the first circuit is coupled to a vertical-cavity surface-emitting laser (VCSEL);
an optical medium, wherein the optical medium is coupled optically to an optical coupler;
a wavelength-dependent optical element (WDOE), wherein the WDOE is further coupled to the optical medium; and
a second circuit;
wherein the system is configured to:
send electrical data, by the first circuit, to the VCSEL;
modulate a wavelength of the VCSEL, wherein the modulating includes emitting, by the VCSEL, a wavelength-modulated beam (WMB), wherein the WMB is based on the electrical data that was sent;
couple optically, by the optical coupler, the WMB to the optical medium;
decode, by the WDOE, the WMB into the electrical data that was sent; and
deliver the electrical data to the second circuit.
